(19) United States
(12) Patent Application Publication
(10) Pub. No.: US 2025/0151504 A1
(43) Pub. Date: May 8, 2025

(54) ARRAY SUBSTRATE, DISPLAY PANEL AND DISPLAY APPARATUS

(71) Applicant: BOE Technology Group Co., Ltd., Beijing (CN)

(72) Inventors: Guangcai YUAN, Beijing (CN); Hehe HU, Beijing (CN); Changhan HSIEH, Beijing (CN); Wei YANG, Beijing (CN); Liwen DONG, Beijing (CN); Jiayu HE, Beijing (CN); Dongfei HOU, Beijing (CN); Zhen ZHANG, Beijing (CN); Ce NING, Beijing (CN); Xin GU, Beijing (CN); Zhengliang LI, Beijing (CN)

(73) Assignee: BOE Technology Group Co., Ltd., Beijing (CN)

(21) Appl. No.: 19/017,860

(22) Filed: Jan. 13, 2025

Related U.S. Application Data
(63) Continuation of application No. PCT/CN2022/139751, filed on Dec. 16, 2022.

(51) Int. Cl. H10K 10/46; G02F 1/1333; G02F 1/1362; H10K 19/10

(52) U.S. Cl. CPC H10K 10/471; G02F 1/133305; G02F 1/136222; H10K 19/10

(57) ABSTRACT

An array substrate includes a base substrate, a first conductive layer, a first electrode, an organic planarization layer and an organic active layer. The first conductive layer is provided on a side of the base substrate. The first electrode is provided on a side of the first conductive layer away from the base substrate, an orthographic projection of the first electrode on the base substrate overlapping an orthographic projection of the drain electrode on the base substrate. The organic planarization layer is provided on a side of the first electrode away from the base substrate, first via holes being provided in the organic planarization layer. The organic active layer is provided on a side of the organic planarization layer away from the base substrate, the organic active layer being connected to the source electrode by a first via hole and connected to the drain electrode by a first via hole.

### CROSS-REFERENCE TO RELATED APPLICATION

This disclosure is a U.S. Continuation application of International Application No. PCT/CN2022/139751, filed on Dec. 16, 2022, entitled “Array Substrate, Display Panel and Display Apparatus”, the content of which is incorporated herein by reference in its entirety.

### TECHNICAL FIELD

The present disclosure relates to the field of display technology, in particular to an array substrate, a display panel and a DISPLAY apparatus.

### BACKGROUND

Flexible DISPLAY apparatus are favored by consumers due to their good flexibility, light and thin volume, low power consumption and rubbing resistance. Flexible OLED (Organic Electroluminescence Display) DISPLAY apparatus have been mature, but flexible LCD (Liquid Crystal Display) devices cannot achieve mass production.

### SUMMARY

An objective of the present disclosure is to overcome deficiencies of the aforementioned existing art, it is provided with an array substrate, a display panel and a DISPLAY apparatus.

According to one aspect of the present disclosure, it is provided with an array substrate, including:

a base substrate;

a first conductive layer disposed on a side of the base substrate, the first conductive layer including a source electrode and a drain electrode;

a first electrode disposed on a side of the first conductive layer away from the base substrate, an orthographic projection of the first electrode on the base substrate being overlapped with an orthographic projection of the drain electrode on the base substrate;

an organic planarization layer disposed on a side of the first electrode away from the base substrate, the organic planarization layer being provided with first via holes, and the first via holes are connected to the source electrode and the drain electrode, respectively;

an organic active layer disposed on a side of the organic planarization layer away from the base substrate, the organic active layer being connected to the source electrode through the first via hole and connected to the drain electrode through the first via hole.

In an exemplary embodiment of the present disclosure, an angle between a hole wall of the first via hole and a face of the first conductive layer away from the base substrate is less than or equal to 70°.

In an exemplary embodiment of the present disclosure, an area of the organic planarization layer corresponding to a display area of a sub-pixel is provided with an opening portion.

In an exemplary embodiment of the present disclosure, an orthographic projection of the display area on the base substrate is located within an orthographic projection of the opening portion on the base substrate.

In an exemplary embodiment of the present disclosure, the array substrate further includes:

a gate insulating layer set disposed on a side of the organic active layer away from the base substrate, and an orthographic projection of the gate insulating layer set on the base substrate being overlapped with an orthographic projection of the organic active layer on the base substrate;

a first gate electrode layer disposed on a side of the gate insulating layer set away from the base substrate, the first gate electrode layer including a first gate electrode.

In an exemplary embodiment of the present disclosure, the gate insulating layer set includes:

a first gate insulating layer disposed on a side of the organic active layer away from the base substrate;

a second gate insulating layer disposed on a side of the first gate insulating layer away from the base substrate, performance of the second gate insulating layer blocking an etching solution of the first gate electrode layer being stronger than performance of the first gate insulating layer blocking an etching solution of the first gate electrode layer.

In an exemplary embodiment of the present disclosure, an orthographic projection of the first gate electrode on the base substrate is within an orthographic projection of the organic active layer on the base substrate.

In an exemplary embodiment of the present disclosure, the organic active layer includes:

a conductor portion, an orthographic projection of the conductor portion on the base substrate is not overlapped with an orthographic projection of the first gate electrode on the base substrate.

In an exemplary embodiment of the present disclosure, in the first direction, a distance between two first via holes of a thin film transistor is larger than a width of the first gate electrode.

In an exemplary embodiment of the present disclosure, the array substrate further includes:

a passivation layer disposed on a side of the first gate electrode layer away from the base substrate;

a second electrode layer disposed on a side of the passivation layer away from the base substrate.

In an exemplary embodiment of the present disclosure, the array substrate further includes:

a second gate electrode layer disposed between the passivation layer and the second electrode layer, wherein the second gate electrode layer includes a second gate electrode and a second gate line, the second gate electrode is connected to the first gate electrode, the second gate line extends along a first direction, the second gate line is connected to a plurality of second gate electrodes disposed along the first direction, and the first direction is parallel to a face of the base substrate close to the first conductive layer.

In an exemplary embodiment of the present disclosure, the first gate electrode layer further includes a first gate line, the first gate line extends along a first direction, the first gate line is connected to a plurality of first gate electrodes disposed along the first direction, and the first direction is parallel to a face of the base substrate close to the first conductive layer.

In an exemplary embodiment of the present disclosure, the array substrate further includes:

a protective layer t covering at least a sidewall of the organic active layer.

In an exemplary embodiment of the present disclosure, the protective layer is disposed between the gate insulating layer set and the first gate electrode, and between the organic planarization layer and the passivation layer, and covers sidewalls of the organic active layer and the gate insulating layer set.

In an exemplary embodiment of the present disclosure, the protective layer is disposed between the first gate electrode layer and the organic planarization layer and the passivation layer, and covers sidewalls of the organic active layer, the gate insulating layer set, and the first gate electrode, and compatibility between the protective layer and the organic active layer is stronger than compatibility between the passivation layer and the organic active layer.

In an exemplary embodiment of the present disclosure, a work function of the first conductive layer is greater than 4.5 eV.

In an exemplary embodiment of the present disclosure, the array substrate is a flexible array substrate.

According to another aspect of the present disclosure, it is provided with a display panel, including:

an array substrate, which is any one of the array substrates described above;

a color film substrate disposed opposite to the array substrate;

a liquid crystal layer disposed between the array substrate and the color film substrate.

In an exemplary embodiment of the present disclosure, the array substrate is a flexible array substrate, and the color film substrate is a flexible color film substrate.

According to another aspect of the present disclosure, it is provided with a DISPLAY apparatus, including: the display panel according to any one of the above embodiments, wherein the DISPLAY apparatus is a rollable DISPLAY apparatus, a foldable DISPLAY apparatus or a curved DISPLAY apparatus.

It should be understood that the above general description and the following detailed description are only exemplary and explanatory, and are not construed as limiting the present disclosure.

### BRIEF DESCRIPTION OF THE DRAWINGS

The figures incorporated herein form a part of the specification and illustrate embodiments consistent with the present disclosure. It will be apparent to those skilled in the art that the embodiments described below are merely exemplary and that other embodiments may be utilized without departing from the spirit and scope of the present disclosure. The figures described below are merely some embodiments of the present disclosure, and it is evident to those skilled in the art without any creative labor that additional embodiments may be obtained based on these figures.

FIG. 1 is a schematic structural view of an array substrate according to a first exemplary embodiment of the present disclosure.

FIG. 2 is a schematic structural view of an array substrate according to a second exemplary embodiment of the present disclosure.

FIG. 3 is a schematic structural view of an array substrate according to a third exemplary embodiment of the present disclosure.

FIG. 4 is a schematic structural view of an array substrate according to a fourth exemplary embodiment of the present disclosure.

FIG. 5 is a schematic structural view of an array substrate according to a fifth exemplary embodiment of the present disclosure.

FIG. 6 is a schematic structural view of an array substrate according to a sixth exemplary embodiment of the present disclosure.

FIG. 7 is a schematic structural view of an array substrate according to a seventh exemplary embodiment of the present disclosure.

Reference numbers are provided as follows:

1 base substrate; 21 first planarization layer; 22 second planarization layer; 3 light shielding layer;
4 first conductive layer; 41 source electrode; 42 drain electrode; 5 first electrode;
6 organic planarization layer; 61 first via hole; 62 opening portion; 7 organic active layer;
8 gate insulating layer set; 81 first gate insulating layer; 82 second gate insulating layer;
91 first gate electrode; 92 second gate electrode;
10 passivation layer; 101 second via hole;
11 second electrode layer; 111 second electrode; 112 conductive enhancement portion;
12 bonding layer; 13 glass substrate; 14 protective layer;
X first direction; Z third direction.

### DETAILED DESCRIPTION

Exemplary embodiments will now be described more fully by reference to the accompanying drawings. However, the exemplary embodiments can be implemented in various forms and should not be understood as being limited to the examples set forth herein; rather, the embodiments are provided so that this disclosure will be thorough and complete, and the conception of exemplary embodiments will be fully conveyed to those skilled in the art. The same reference signs in the drawings denote the same or similar structures and detailed description thereof will be omitted. In addition, the drawings are merely schematic illustrations of the present disclosure and are not necessarily drawn to scale.

Although relative terms such as “above” and “under” are used herein to describe the relationship of one component relative to another component, such terms are used herein only for the sake of convenience, for example, in the direction shown in the figure, it should be understood that if the referenced device is inversed upside down, a component described as “above” will become a component described as “under”. When a structure is described as “above” another structure, it probably means that the structure is integrally formed on another structure, or, the structure is “directly” disposed on another structure, or, the structure is “indirectly” disposed on another structure through an additional structure.

Words such as “one”, “an/a”, “the” and “said” are used herein to indicate the presence of one or more elements/component parts/and others. Terms “including”, and “having” have an inclusive meaning which means that there may be additional elements/component parts/and others in addition to the listed elements/component parts/and others. Terms “first”, “second”, “third” and “fourth” are used herein only as markers, and they do not limit the number of objects modified after them.

In the present disclosure, unless otherwise specifically defined and limited, the term “connection” should be understood in a broad sense, for example, the “connection” may be a fixed connection, a detachable connection, or an integral one; it may be a direct connection or an indirect connection through an intermediary. The term “and/or” merely describes relationship between associated objects, indicating that there may be three relationships, for example, A and/or B, representing the presence of A alone, the presence of both A and B together, or the presence of B alone. Furthermore, a character “/” herein generally indicates a “or” relationship between the associated objects.

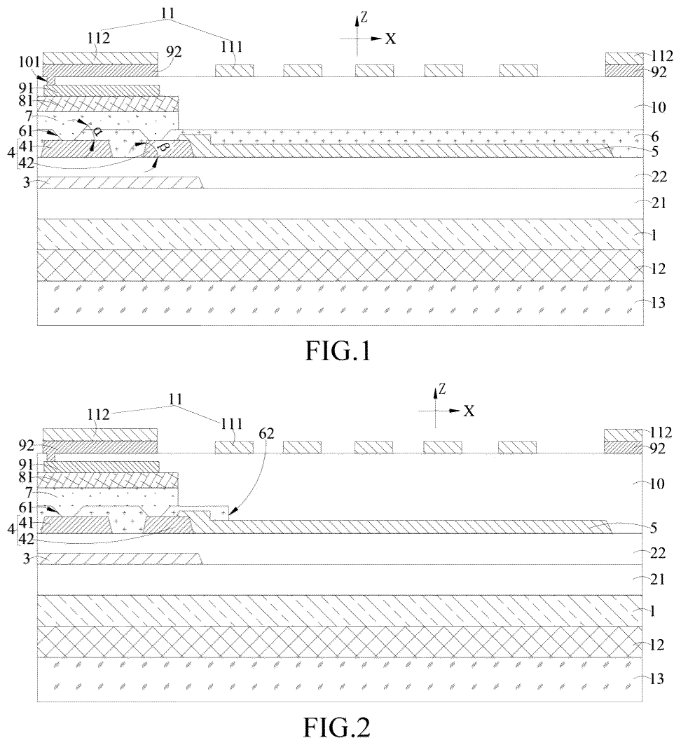

An exemplary embodiment of the present disclosure provides an array substrate. Referring to FIG. 1 to FIG. 7, the array substrate may include a base substrate 1, a first conductive layer 4, a first electrode 5, an organic planarization layer 6, and an organic active layer 7. The first conductive layer 4 is disposed on a side of the base substrate 1. The first conductive layer 4 includes a source electrode 41 and a drain electrode 42. The first electrode 5 is disposed on a side of the first conductive layer 4 away from the base substrate 1, and an orthographic projection of the first electrode 5 on the base substrate 1 is overlapped with an orthographic projection of the drain electrode 42 on the base substrate 1. The organic planarization layer 6 is disposed on a side of the first electrode 5 away from the base substrate 1. First via holes 61 are disposed on the organic planarization layer 6 and are connected to the source electrode 41 and the drain electrode 42, respectively. The organic active layer 7 is disposed on a side of the organic planarization layer 6 away from the base substrate 1, and the organic active layer 7 is connected to the source electrode 41 through the first via hole 61 and to the drain electrode 42 through the first via hole 61.

In the array substrate of the present disclosure, on one hand, an organic planarization layer 6 is disposed on a side of the first electrode 5 away from the base substrate 1. The organic planarization layer 6 is provided with first via holes 61. The organic active layer 7 is connected to the source electrode 41 through the first via hole 61, and is connected to the drain electrode 42 through the first via hole 61. This can prevent the organic active layer 7 from climbing a sidewall of the first conductive layer 4, prevent gaps that may arise when the organic active layer 7 climbs the sidewall of the first conductive layer 4, and thereby preventing the organic active layer 7 from breaking due to the gaps. Furthermore, when the organic active layer 7 is directly in contact with the first conductive layer 4, it is necessary to set a thickness of the first conductive layer 4 to be relatively small to avoid a high climbing height for the organic active layer 7. The material of the first conductive layer 4 may also be considered to prevent the sidewalls formed by the first conductive layer 4 from having a steep slope, when the organic active layer 7 is connected to the first conductive layer 4 through the first via hole 61, it can reduce the requirements for the material and thickness of the first conductive layer 4, that is, the thickness of the first conductive layer 4 may be set to be thicker in order to enhance conductivity of the first conductive layer 4; this can makes the array substrate suitable for mass production. On the other hand, the array substrate uses an organic active layer 7 and an organic planarization layer 6, so that the array substrate has sufficient flexibility to be used in flexible display panels.

The array substrate may be a flexible array substrate. Therefore, the base substrate 1 may be a flexible substrate. The material of the base substrate 1 is a flexible material, and specifically, the material of the base substrate 1 may be a resin material such as a cellulose triacetate film, polyimide, polycarbonate, polyacrylate, polyetherimide, polyethersulfone, polyethylene terephthalate, and polyethylene naphthalate. The base substrate 1 may be formed of a plurality of material layers, for example, the base substrate 1 may include a plurality of base material layers. The material of the base material layer may be any one of the above materials. Certainly, the base substrate 1 may also be provided as a single layer, which may be any one of the materials described above.

In order to facilitate the preparation and the transportation of the array substrate, the base substrate 1 may be bonded to the glass substrate 13 through a bonding layer 12, and the glass substrate 13 is peeled off during use. Certainly, when the array substrate is used as a rigid base substrate 1, the glass substrate 13 may not be peeled off, or the glass substrate 13 may not be used, and other hard substrates may be used.

A plurality of thin film transistors arranged in an array may be disposed on a side of the base substrate 1. The thin film transistors may at least include a source electrode 41, a drain electrode 42, an organic active layer 7, and a first gate electrode 91. Materials and structures of the source electrode 41, the drain electrode 42, the organic active layer 7 and the first gate electrode 91 are main factors for determining whether the performance of the thin film transistor is qualified and whether mass production can be performed. At present, the array substrates are not mass produced due to the above grounds.

Referring to FIG. 1 to FIG. 5, a first planarization layer 21 may be disposed on a side of the base substrate 1. A material of the first planarization layer 21 has a relatively strong adhesion, a relatively strong corrosion resistance to chemical solvent, relatively good planarization effect, and relatively high light transmission; and the material of the first planarization layer 21 has a low polarity to reduce a channel effect and reduce a leakage current. The material of the first planarization layer 21 may be an epoxy resin photoresist, for example, an SU-8 series epoxy resin photoresist. A side of the first planarization layer 21 away from the base substrate 1 is provided with a light shielding layer 3. Lights incident into the organic active layer 7 from the side of the base substrate 1 may generate photo-generated carriers in the organic active layer 7, thereby greatly affecting characteristics of the thin film transistor and finally affecting the display image quality of the Display apparatus. The lights incident from the side of the base substrate 1 may be shielded by the light shielding layer 3, thereby avoiding any impact on the characteristics of the thin film transistor and avoiding any affect on the display image quality of the display apparatus. Depending on the type of the thin film transistor, the light-shielding layer 3 may be omitted.

A second planarization layer 22 may be disposed on a side of the light shielding layer 3 away from the base substrate 1. A material of the second planarization layer 22 is an insulating material. The second planarization layer 22 may insulate and isolate the light shielding layer 3 from the first conductive layer 4. The material of the second planarization layer 22 has relatively strong adhesive force, relatively strong corrosion resistance to chemical solvent, relatively good planarization effect, and high light transmission. The material of the second planarization layer 22 has a low polarity to reduce the channel effect and reduce the leakage current. Specifically, the material of the second planarization layer 22 may be an epoxy resin photoresist, for example, an SU-8 series epoxy resin photoresist.

A first conductive layer 4 may be disposed on a side of the second planarization layer 22 away from the base substrate 1. The first conductive layer 4 may include a source electrode 41, a drain electrode 42, and a data cable. The data cable may extend along a second direction, and the data cable is connected to a plurality of source electrodes 41 disposed along the second direction, or a part of the data cable may be used as the source electrode 41.

A thickness of the first conductive layer 4 is greater than or equal to 500 Å (angstroms) and less than or equal to 8000 Å. For example, the thickness of the first conductive layer 4 may be 650 Å, 982 Å, 1020 Å, 1190 Å, 1380 Å, 1850 Å, 2340 Å, 2840 Å, 3240 Å, 3840 Å, 4180 Å, 4586 Å, 5170 Å, 5760 Å, 6230 Å, 6840 Å, 7520 Å, 7850 Å, or etc.

A first electrode 5 may be disposed on a side of the first conductive layer 4 away from the base substrate 1. The first electrode 5 may be pixel electrodes. The pixel electrodes and a common electrode form different electric fields to control the orientation of the liquid crystals to realize the display in individual sub-pixels. The display area of the sub-pixels is an area where the individual sub-pixels can be displayed. Therefore, the display area of the sub-pixels may be an area of the first electrode 5 excluding the portion connected to the drain electrode 42. And the first electrode 5 of two adjacent sub-pixels are spaced apart. The material of the first electrode 5 may be a transparent conductive material, such as ITO (indium tin oxide), IZO (indium zinc oxide), or the like.

An orthographic projection of the first electrode 5 on the base substrate 1 may be overlapped with an orthographic projection of the drain electrode 42 on the base substrate 1, that is, a part of the first electrode 5 may be disposed on a side of the drain electrode 42 away from the base substrate 1, so that the first electrode 5 may be directly electrically connected to the drain electrode 42; and another part of the first electrode 5 may be disposed on a side of the second planarization layer 22 away from the base substrate 1.

Certainly, in some other exemplary embodiments of the present disclosure, the orthographic projection of the first electrode 5 on the base substrate 1 may be overlapped with the orthographic projection of the source electrode 41 on the base substrate 1, that is, a part of the first electrode 5 may be disposed on a side of the source electrode 41 away from the base substrate 1, so that the first electrode 5 may be directly electrically connected to the source electrode 41; and another part of the first electrode 5 may be disposed on a side of the second planarization layer 22 away from the base substrate 1.

It should be noted that in cases where thin-film transistors with opposite polarities are used, or when the direction of current changes during circuit operation, the functions of the “source electrode 41” and the “drain electrode 42” may sometimes be interchanged. Thus, in the present specification, the “source electrode 41” and the “drain electrode 42” may be interchanged.

An organic planarization layer 6 may be disposed on a side of the first electrode layer 5 away from the base substrate 1. A material of the organic planarization layer 6 may be an organic material, specifically, the material of the organic planarization layer 6 may be resistant to a chemical solvent, and may play a role in protecting the first conductive layer 4. Furthermore, the material of the organic planarization layer 6 has high light transmittance to avoid affecting the light transmittance of the display panel. The material of the organic planarization layer 6 has a low polarity, which refers to a small dipole moment within molecules and a relatively uniform charge distribution. In simple terms, this means that the molecules are relatively symmetrical and generally have few lone pairs of electrons. Low polarity can reduce the formation of induced charges that lead to polarization, thereby reducing back channel effect and leakage current. For example, the material of the organic planarization layer 6 may be SU-8 series epoxy photoresist, and other low dielectric constant materials may also be selected.

The thickness of the organic planarization layer 6 is greater than or equal to 300 nm and less than or equal to 800 nm. For example, the thickness of the organic planarization layer 6 may be 326 nm, 375 nm, 430 nm, 480 nm, 517 nm, 589 nm, 625 nm, 673 nm, 741 nm, 789 nm, or the like.

A plurality of first via holes 61 are provided on the organic planarization layer 6, and the first via holes 61 are connected to the source electrode 41 and the drain electrode 42, respectively.

An organic active layer 7 may be disposed on a side of the organic planarization layer 6 away from the base substrate 1. The organic active layer 7 is connected to the source electrode 41 through the first via hole 61, and the organic active layer 7 is connected to the drain electrode 42 through the first via hole 61. The material of the organic active layer 7 may be an organic semiconductor (OSC) material.

When the organic active layer 7 is directly in contact with and connected to the first conductive layer 4, the thickness of the first conductive layer 4 is set to be small, to avoid that a climbing height of the organic active layer 7 is too high, and the material of the first conductive layer 4 also may be considered, to avoid that a slope of the sidewall formed by the first conductive layer 4 is steep. However, the slope of the sidewall of the first conductive layer 4 is also relatively steep, for example, an angle between the sidewall of the first conductive layer 4 and the face of the base substrate 1 close to the first conductive layer 4 is generally greater than 70°, and a sharp corner structure is easily formed at a corner of the side of the first conductive layer 4 away from the base substrate 1; the organic active layer 7 subsequently formed may form a gap on the sidewall of the first conductive layer 4. Due to the presence of gaps, the organic active layer 7 is prone to fracture, leading to open circuits; moreover, the presence of sharp corner structures, the organic active layer 7 has poor coverage at the corner on the side of the first conductive layer 4 away from the base substrate 1, which can also easily lead to fractures in the organic active layer 7, thereby causing open circuits.

When the organic active layer 7 is connected to the source electrode 41 and the drain electrode 42 through the first via holes 61, an angle α between a hole wall of the first via hole 61 and a face of the first conductive layer 4 away from the base substrate 1 is smaller than an angle β between a sidewall of the first conductive layer 4 and the face of the base substrate 1 close to the first conductive layer 4, that is, an inclination angle of the hole wall of the first via hole 61 is smaller than an inclination angle of the sidewalls of the source electrode 41 and the drain electrode 42 of the first conductive layer 4. Specifically, the angle α between the hole wall of the first via hole 61 and the face of the first conductive layer 4 away from the base substrate 1 is less than or equal to 70°; that is, although the first via hole 61 has a hole wall, the slope of the hole wall of the first via hole 61 is relatively gentle, and even if the organic active layer 7 subsequently formed climbs the hole wall of the first via hole 61, there will be no gap, and thereby avoiding the fracture of the organic active layer 7 due to the presence of the gaps.

In addition, the material of the organic planarization layer 6 is an organic material, a corner of the organic planarization layer 6 is relatively round and smooth, and the corner of the organic planarization layer 6 may be an arc surface, that is, a face of the organic planarization layer 6 away from the base substrate 1 is connected to a hole wall of the first via hole 61 through the arc surface. The sharp corner structures of the corners of the source electrode 41 and the drain electrode 42 are not formed. Therefore, the organic active layer 7 subsequently formed has better coverage at the corner of the organic planarization layer 6, and does not cause poor breakage at a corner bending portion.

Furthermore, the angle α between the hole wall of the first via hole 61 and the face of the first conductive layer 4 away from the base substrate 1 may not be too small. If the angle α is too small, the area of the first via hole 61 is relatively large, so that the area of the organic active layer 7 subsequently formed is relatively large, the area of the entire thin film transistor is relatively large, and an opening ratio of the display panel can be affected. Specifically, the angle α between the hole wall of the first via hole 61 and the face of the first conductive layer 4 away from the base substrate 1 is greater than or equal to 30°. For example, the angle α between the hole wall of the first via hole 61 and the face of the first conductive layer 4 away from the base substrate 1 may be 32°, 36°, 42.5°, 46.8°, 51°, 54.7°, 58.4°, 62°, 65.3°, 67.5°, or etc.

A distance between the face of the organic planarization layer 6 away from the base substrate 1 and the first conductive layer 4 is less than a thickness of the first conductive layer 4 in the third direction Z, that is, a depth of the first via hole 61 is less than the thickness of the first conductive layer 4; the third direction Z is perpendicular to the face of the base substrate 1 close to the first electrode 5. This allows the organic active layer 7 subsequently formed to climb the sidewalls of the organic planarization layer 6, but with a low climbing height, further preventing the formation of gaps in the organic active layer 7, and avoiding fractures due to the gaps.

Furthermore, due to the planarization and protective effect of the organic planarization layer 6, there is more room for selection of the material of the first conductive layer 4, enabling mass production of the flexible array substrate. Furthermore, since the organic semiconductor (OSC) material of the organic active layer 7 is a P-type material, the first conductive layer 4 may form ohmic contact with the organic active layer 7, and the first conductive layer 4 may select a material with a higher work function, for example, the work function of the material of the first conductive layer 4 may be greater than 4.5 eV. Considering the work function, the material of the first conductive layer 4 may be Ag+SAM, with the work function that is about 5.86 eV, and Ag that is closer to the base substrate 1; it may be ITO (indium tin oxide), with the work function that is greater than or equal to 4.57 and less than or equal to 4.93 eV; it may be Mo+surface oxidation (molybdenum oxide), with that work function that is about 5.58 eV, and Mo that is closer to the base substrate 1; it may be Mo alloy+surface oxidation (molybdenum oxide), with the work function that is about 5.5 eV, and Mo alloy that is closer to the base substrate 1; it may also be TiN, with the work function that is greater than or equal to 4.49 and less than or equal to 5.29 eV; it may also be Au, with the work function that is about 5.2 eV; it may also be Pt, with the work function that is about 5.6 eV; it may also be Pd, with the work function that is about 5.12 eV, etc.

Considering the performance of conductivity, the first conductive layer 4 may adopt a laminated structure, for example, the first conductive layer 4 may include BF (Buffer Film), LRF (Low Resistance Film), and HWF (High Work Function Film) stacked in sequence. The buffer film is closer to the base substrate 1. The buffer film may be selected from Mo, Mo alloy, Ti, ITO, IZO (indium zinc oxide) and the like. The low resistance film may be selected from Cu, Al, Ag and the like. The high work function film may be Ag+SAM, with the work function that is about 5.86 eV, and Ag that is closer to the base substrate 1; it may be ITO (indium tin oxide), with the work function that is greater than or equal to 4.57 and less than or equal to 4.93 eV; it may be Mo+surface oxidation (molybdenum oxide), with the work function that is about 5.58 eV, and Mo that is closer to the base substrate 1; it may be Mo alloy+surface oxidation (molybdenum oxide), with the work function that is about 5.5 eV, and Mo alloy that is closer to the base substrate 1; it may also be TiN, with the work function that is greater than or equal to 4.49 and less than or equal to 5.29 eV; it may also be Au, with the work function that is about 5.2 eV; it may also be Pt, with the work function that is about 5.6 eV; it may also be Pd, with the work function that is about 5.12 eV, etc.

The SAM, which is a self-assembled monolayer film, may form a monolayer and modify the interface between the first conductive layer 4 and the organic active layer 7 to improve the work function.

In addition, in some other exemplary embodiments of the present disclosure, as shown in FIG. 2, an area of the organic planarization layer 6 corresponding to the display area of the sub-pixel is provided with an opening portion 62, that is, the organic planarization layer 6 is provided with an opening portion 62, the opening portion 62 corresponds to the display area of the sub-pixel, and an orthographic projection of the display area on the base substrate 1 is within an orthographic projection of the opening portion 62 on the base substrate 1, so that only one passivation layer 10 is disposed between the first electrode 5 and the second electrode 111 in the display area of the sub-pixel, so that the electric field of the display area of the sub-pixel can be maintained without being affected by the organic planarization layer 6.

Furthermore, the angle α between the hole wall of the first via hole 61 and the face of the first conductive layer 4 away from the base substrate 1 is less than or equal to 70°, so that the slope of the hole wall of the first via hole 61 is relatively smooth, the organic active layer 7 is connected to the source electrode 41 and the drain electrode 42 through the first via hole 61, the climbing slope of the organic active layer 7 in the first via hole 61 is relatively smooth, there is no gap formed between the organic active layer 7 and the hole wall of the first via hole 61, to prevent fractures in the organic active layer 7. Furthermore, it is not necessary to consider the thickness of the first conductive layer 4, that is, the thickness of the first conductive layer 4 may not be set relatively thin to meet the climbing slope of the organic active layer 7, so that the conductivity of the first conductive layer 4 can be improved.

In this exemplary embodiment, a gate insulating layer set 8 may be disposed on a side of the organic active layer 7 away from the base substrate 1, and an orthographic projection of the gate insulating layer set 8 on the base substrate 1 is overlapped with an orthographic projection of the organic active layer 7 on the base substrate 1, that is, the orthographic projection of the gate insulating layer set 8 on the base substrate 1 completely coincides with the orthographic projection of the organic active layer 7 on the base substrate 1. This allows the gate insulating layer set 8 and the organic active layer 7 to be formed in the same patterning process, to reduce the process steps and the costs.

It should be noted that the so-called “overlap” is not completely overlapped, but allow for some errors. Depending on the equipment and manufacturing processes used, the error range may vary. Therefore, as long as the overlapping is within the error range of the equipment and manufacturing processes, it is considered to be overlapped.

Referring to FIG. 1 and FIG. 2, the gate insulating layer set 8 may include a first gate insulating layer 81, and the first gate insulating layer 81 may be a flexible film layer and has insulation; and the first gate insulating layer 81 is orthogonal to the solvent for etching the organic active layer 7 and has poor compatibility performance, that is, the material of the first gate insulating layer 81 does not react with the material of the organic active layer 7 to ensure channel characteristics of the organic active layer 7; specifically for example, the material of the first gate insulating layer 81 may be a material with a low dielectric constant.

It should be noted that the orthogonal solvent refers to a solvent with significantly different polarities. An orthogonal solvent system is a type of solvent system used for applying subsequent layers. The previously applied layers are insoluble in the solvent system.

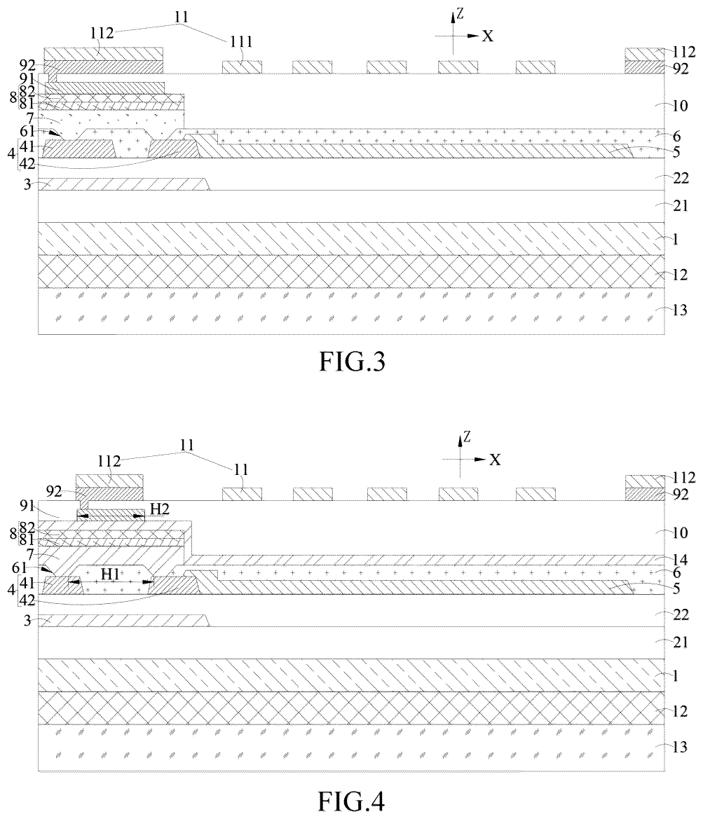

Referring to FIG. 3, the gate insulating layer set 8 may further include a second gate insulating layer 82 disposed on a side of the first gate insulating layer 81 away from the base substrate 1, and performance of the second gate insulating layer 82 blocking the etching solution of the first gate electrode layer is stronger than performance of the first gate insulating layer 81 blocking the etching solution of the first gate electrode layer. The second gate insulating layer 82 may be a flexible film layer, which has insulation, excellent environmental stability, and can resist water and oxygen; it may be a crosslinked material, which is a material subjected to a crosslinking reaction, and the crosslinking reaction refers to a relatively stable molecular (bulk molecular) reaction in which two or more molecules (generally linear molecules) are mutually bonded and crosslinked into a network structure. This reaction converts linear or lightly branched macromolecules into a three-dimensional network structure, thereby improving strength, heat resistance, wear resistance, solvent resistance and other properties; specifically for example, the material of the second gate insulating layer 82 may be a crosslinked dielectric material, which can improve electrical durability.

A first gate electrode layer may be disposed on a side of the gate insulating layer set 8 away from the base substrate 1, and the first gate electrode layer may include a first gate electrode 91.

A preparation process of the first gate electrode layer, the gate insulating layer set 8 and the organic active layer 7 is as follows: sequentially forming an organic active material layer, a gate insulating material layer set and a first gate electrode material layer on a side of the organic planarization layer 6 away from the base substrate 1, forming a first mask layer on a side of the first gate electrode material layer away from the base substrate 1, exposing and developing the first mask layer to form a required pattern, etching the first gate electrode material layer to form the first gate electrode layer, and removing the first mask layer; and then forming a second mask layer on a side of the first gate electrode layer away from the base substrate 1, exposing and developing the second mask layer to form a required pattern, etching the gate insulating material layer set and the first gate electrode material layer to form the gate insulating layer set 8 and the first gate electrode layer, and removing the second mask layer.

In the case where the gate insulating layer set 8 includes only the first gate insulating layer 81, a channel portion of the organic active layer 7 has the first gate electrode 91 for shielding protection, but other areas are not shielded and protected by the first gate electrode 91. Since the first gate insulating layer 81 and the organic active layer 7 are poor in blocking property, when etching the first gate electrode material layer, the etching solution easily penetrates through the first gate insulating layer 81 and the organic active layer 7 to corrode the first conductive layer 4. Therefore, there are requirements for the selection of materials of the first gate electrode layer, and it is necessary for the etching solution of the first gate electrode layer to have no corrosion effect on the first conductive layer 4, that is, when the first gate electrode layer is formed by etching, the first conductive layer 4 may not be corroded, specifically for example, the material of the first gate electrode layer may be ITO (indium tin oxide), IZO (indium zinc oxide), or the like. The thickness of the first gate electrode layer is greater than or equal to 400 Å and less than or equal to 1500 Å. For example, the thickness of the first gate electrode layer may be 430 Å, 478 Å, 536 Å, 569 Å, 634 Å, 689 Å, 721 Å, 758 Å, 830 Å, 978 Å, 1036 Å, 1169 Å, 1234 Å, 1389 Å, 1421 Å, 1458 Å, and etc.

When the gate insulating layer set 8 includes the first gate insulating layer 81 and the second gate insulating layer 82, the performance of the second gate insulating layer 82 blocking the etching solution of the first gate electrode layer is stronger than the performance of the first gate insulating layer 81 blocking the etching solution of the first gate electrode layer. In the process of etching the first gate electrode material layer, the second gate electrode insulating material layer can protect the first conductive layer 4, so as to prevent the etching solution of the first gate electrode layer from corroding the first conductive layer 4. Therefore, there is a large room for selection of the materials of the first gate electrode layer. For example, the material of the first gate electrode layer may be Ag, Mo, Cu, Al, Ti, ITO, a stacked structure of ITO/Ag/ITO, a stacked structure of Mo/Al/Mo, a stacked structure of Mo/Cu/Mo, a stacked structure of Ti/Al/Ti, and the like.

In some other exemplary embodiments of the present disclosure, the first gate electrode layer may include not only the first gate electrode 91, but also a first gate line (not shown). The first gate line extends along the first direction X, the first gate line is connected to a plurality of first gate electrodes 91 disposed along the first direction X, and the first direction X is parallel to a face of the base substrate 1 close to the first conductive layer 4, that is, one first gate line is connected to a plurality of first gate electrodes 91 in one row, and scanning signals are provided for the first gate electrodes 91 of a plurality of thin film transistors in one row through one first gate line.

In this exemplary embodiment, referring to FIG. 1, a passivation layer 10 may be disposed on a side of the first gate electrode layer away from the base substrate 1. The passivation layer 10 may be a flexible film layer, which has insulation, excellent environmental stability, and can resist water and oxygen, and specifically may be a crosslinked material; the material of the passivation layer 10 may be the same as the material of the second gate insulating layer 82.

The passivation layer 10 is provided with a second via hole 101 that is connected to the first gate electrode 91.

A second electrode layer 11 may be disposed on a side of the passivation layer 10 away from the base substrate 1, and a material of the second electrode layer 11 may be a transparent conductive material, for example, ITO (indium tin oxide), IZO (indium zinc oxide), or the like. The second electrode layer 11 may include a second electrode 111 and a conductive enhancement portion 112. The second electrode 111 is spaced apart from the conductive enhancement portion 112, that is, the second electrode 111 is not connected to the conductive enhancement portion 112. The second electrode 111 may be a common electrode.

In this exemplary embodiment, referring to FIG. 1, the array substrate may further include a second gate electrode layer. The second gate electrode layer is disposed between the passivation layer 10 and the second electrode layer 11. The second gate electrode layer may include a second gate electrode 92 and a second gate line (not shown). The second gate electrode 92 is connected to the first gate electrode 91 through the second via hole 101 on the passivation layer 10, so that the first gate electrode 91 and the second gate electrode 92 jointly act on the organic active layer 7 to turn on and off the thin film transistor. The second gate line extends along the first direction X, and the second gate line is connected to a plurality of second gate electrodes 92 disposed along the first direction X, that is, one second gate line is connected to a plurality of second gate electrodes 92 in one row, and scanning signals are provided for a plurality of thin film transistors in one row through one second gate line.

The material of the second gate electrode layer may be Ag, Mo, Cu, Al, Ti, ITO, a stacked structure of ITO/Ag/ITO, a stacked structure of Mo/Al/Mo, a stacked structure of Mo/Cu/Mo, a stacked structure of Ti/Al/Ti, and the like.

In this case, the conductive enhancement portion 112 covers the second gate electrode 92, and the conductive enhancement portion 112 not only can provide protection for the second gate electrode 92, but also prevent the second gate electrode 92 from being corroded. The material of the conductive enhancement portion 112 is a conductor, which can reduce the resistance of the second gate electrode 92, thereby reducing the power consumption of the thin film transistor.

It should be noted that, in the case where the first gate electrode layer and the second gate electrode layer are provided, the array substrate may include a first gate line and a second gate line, that is, the first gate line and the second gate line may exist simultaneously; or the array substrate may include a first gate line or a second gate line, that is, the first gate line and the second gate line are provided with one of them.

However, since the second electrode 111 is a common electrode, a plurality of second electrodes 111 may be connected as a whole. Furthermore, the second electrode 111 is directly disposed on a side of the second gate electrode layer away from the base substrate, so that the second gate line may be disconnected, so that the plurality of second electrodes 111 may be connected as a whole at the disconnected position of the second gate line. Certainly, in some other example embodiments of the present disclosure, the second gate line may not be disconnected, but the first gate line may be disconnected, and two adjacent second electrodes 111 may be transferred to the first gate electrode layer, so that the plurality of second electrodes 111 may be connected as a whole at the disconnected position of the first gate line.

Further, referring to FIG. 4 and FIG. 5, the array substrate may further include a protective layer 14, the protective layer 14 at least covers a sidewall of the organic active layer 7, and the protective layer 14 may protect the organic active layer 7.

Referring to FIG. 4, the protective layer 14 may be disposed between the gate insulating layer set 8 and the first gate electrode 91, between the organic planarization layer 6 and the passivation layer 10, and cover the sidewall of the organic active layer 7 and the sidewall of the gate insulating layer set 8. That is, the protective layer 14 has been formed before the first gate electrode layer is formed, so that when the first gate electrode material layer is etched to form the first gate electrode layer, the protective layer 14 may protect the organic active layer 7 to prevent the etching solution of the first gate electrode layer from corroding the organic active layer 7, so that there is a relatively large room for selection of the material of the first gate electrode layer, for example, the material of the first gate electrode layer may be Ag, Mo, Cu, Al, Ti, ITO, a stacked structure of ITO/Ag/ITO, a stacked structure of Mo/Al/Mo, a stacked structure of Mo/Cu/Mo, a stacked structure of Ti/Al/Ti, and the like.

The thickness of the protection layer 14 is greater than or equal to 1000 Å and less than or equal to 3000 Å, for example, the thickness of the protection layer 14 may be 1030 Å, 1085 Å, 1162 Å, 1238 Å, 1348 Å, 1586 Å, 1651 Å, 1752 Å, 1830 Å, 1985 Å, 2162 Å, 2338 Å, 2481 Å, 2568 Å, 2615 Å, 2725 Å, 2856 Å, 2965 Å, and etc.

The material of the protective layer 14 may be the same as the material of the second planarization layer 22 or the passivation layer 10, and the specific requirements for the materials of the second planarization layer 22 and the passivation layer 10 have been described above in detail, and details will not be described herein again.

Furthermore, the size of the first gate electrode 91 may be further reduced, so that the orthographic projection of the first gate electrode 91 on the base substrate 1 is within the orthographic projection of the organic active layer 7 on the base substrate 1, for example, the orthographic projection of the organic active layer 7 on the base substrate 1 covers and is larger than the orthographic projection of the first gate electrode 91 on the base substrate 1, so that the organic active layer 7 protrudes from the first gate electrode 91. Specifically, in a first direction X, a distance H1 between two first via holes 61 of the same thin film transistor is greater than a width H2 of the first gate electrode 91. Reducing the area of the first gate electrode 91 can reduce the overlapped area between the first gate electrode 91 and the first conductive layer 4, and reduce capacitance Cgs between the first gate electrode 91 and the source electrode 41 and capacitance Cgd between the first gate electrode 91 and the drain electrode 42, thereby reducing power consumption. The width H2 of the first gate electrode 91 is about 4 micrometers.

Furthermore, the portion of the organic active layer 7 protruding from the first gate electrode 91 may be conductive, so that the organic active layer 7 may include a channel portion and two conductor portions, the two conductor portions are disposed on opposite sides of the channel portion, and the channel portion is a semiconductor. The orthographic projection of the channel portion on the base substrate 1 coincides with the orthographic projection of the first gate electrode 91 on the base substrate 1 while the orthographic projection of the conductor portion on the base substrate 1 is not overlapped with the orthographic projection of the first gate electrode 91 on the base substrate 1.

The organic active layer 7 may be treated with acid gas for plasma or doping, and the acid gas may include CO2 (carbon dioxide), Cl2 (chlorine), H2S (hydrogen sulfide), NO2 (nitrogen dioxide), HCl (hydrogen chloride), SO2 (sulfur dioxide), and the like.

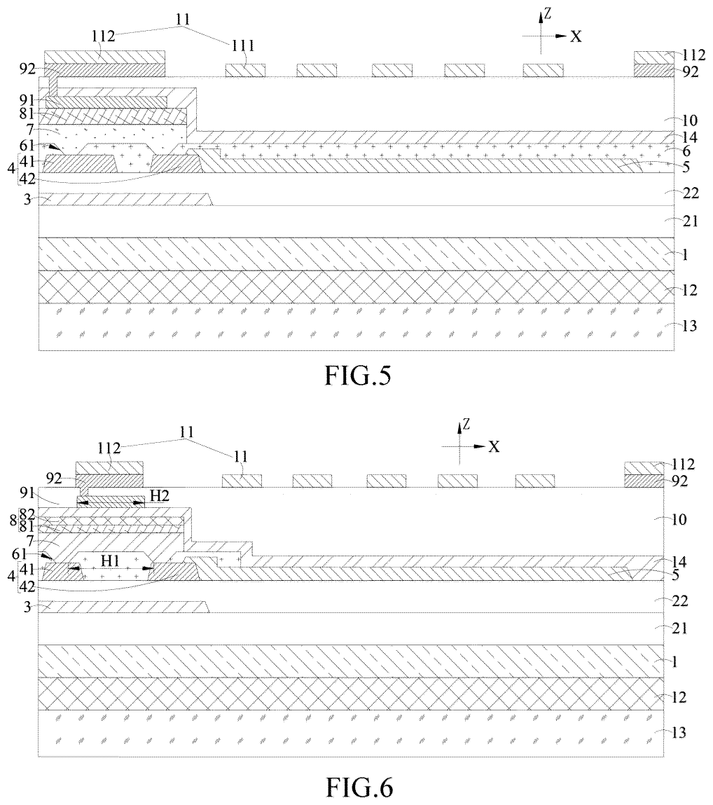

In addition, referring to FIG. 6, in the case where the opening portion 62 is disposed on the organic planarization layer 6, the protective layer 14 may be disposed between the gate insulating layer set 8 and the first gate electrode 91, between the first electrode 5 and the passivation layer 10, and cover the sidewall of the organic active layer 7, the sidewall of the gate insulating layer set 8, and the sidewall of the opening portion 62.

Referring to FIG. 5, the protective layer 14 may be disposed between the first gate electrode layer and the organic planarization layer 6 and the passivation layer 10, and cover the sidewalls of the organic active layer 7, the gate insulating layer set 8, and the first gate electrode 91. That is, the protective layer 14 is formed after the first gate electrode 91 is formed.

The thickness of the protection layer 14 is greater than or equal to 1000 Å and less than or equal to 3000 Å, for example, the thickness of the protection layer 14 may be 1030 Å, 1085 Å, 1162 Å, 1238 Å, 1348 Å, 1586 Å, 1651 Å, 1752 Å, 1830 Å, 1985 Å, 2162 Å, 2338 Å, 2481 Å, 2568 Å, 2615 Å, 2725 Å, 2856 Å, 2965 Å, and etc.

The material of the protective layer 14 may be the same as the material of the first gate insulating layer 81 or the material of the first planarization layer 21. The specific requirements for the material of the first gate insulating layer 81 or the material of the first planarization layer 21 have been described above in detail, and the details will not be described herein again.

The compatibility between the protective layer 14 and the organic active layer 7 is stronger than the compatibility between the passivation layer 10 and the organic active layer 7. The protective layer 14 may prevent the organic active layer 7 from contacting the passivation layer 10. Since the compatibility in materials between the organic active layer 7 and the passivation layer 10 is poor, for example, the organic active layer 7 and the passivation layer 10 may react, and an additional by-product may be generated during the film forming process, or the organic active layer 7 and the passivation layer 10 may be mutually dissolved, resulting in damage to the organic active layer 7 and the passivation layer 10. The compatibility in materials between the protective layer 14 and the organic active layer 7 is relatively good, that is, the material of the protective layer 14 is orthogonal to the material solvent of the organic active layer 7, that is, the material of the protective layer 14 does not react with the material of the organic active layer 7, so that the protective layer 14 and the organic active layer 7 can maintain integrity, the stability of the thin film transistor can be improved, and the performance of the array substrate can be ensured.

In this case, the second gate electrode 92 may be connected to the first gate electrode 91 through the second via hole on the passivation layer 10 and the third via hole on the protection layer 14, and the second via hole on the passivation layer 10 and the third via hole on the protection layer 14 may be formed by the same patterning process.

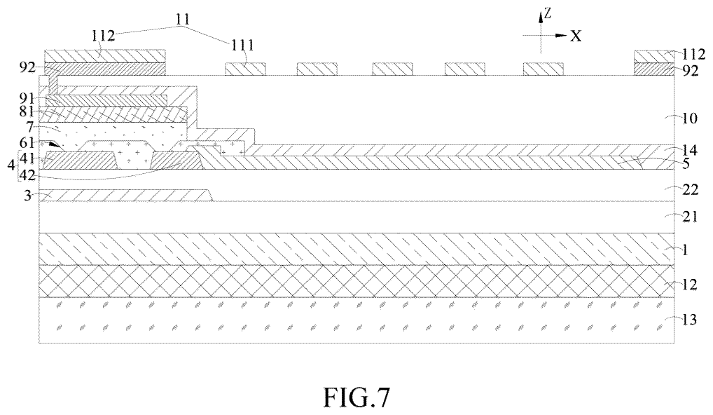

In addition, referring to FIG. 7, in the case where the opening portion 62 is disposed on the organic planarization layer 6, the protective layer 14 may be disposed between the first gate electrode layer and the passivation layer 10, and cover the sidewall of the organic active layer 7, the sidewall of the gate insulating layer set 8, the sidewall of the first gate electrode 91, and the sidewall of the opening portion 62.

Based on the same inventive concept, exemplary embodiments of the present disclosure provide a display panel. The display panel is a liquid crystal display panel. The display panel may include an array substrate, a color film substrate and a liquid crystal layer. The array substrate may be any one of the array substrates described above, and the specific structure of the array substrate has been described above in detail, and therefore, details will not be described herein again. The color film substrate is disposed opposite to the array substrate; and the liquid crystal layer is disposed between the array substrate and the color film substrate.

The array substrate may be a flexible array substrate; and the color film substrate may be a flexible color film substrate, so that the display panel is a flexible display panel. The color film substrate may include a flexible substrate, a light shielding portion and a light filtering portion disposed on a side of the flexible substrate, and the light filtering portion may include a red light filtering portion, a green light filtering portion, a blue light filtering portion, and the like.

Based on the same inventive concept, exemplary embodiments of the present disclosure provide a display apparatus, which may be a rollable display apparatus, a foldable display apparatus, a curved display apparatus, or the like. The display apparatus may include any one of the display panels described above, and the specific structure of the display panel has been described above in detail, and the details will not be described herein again.

The specific types of the display apparatus may not particularly limited, and the types of display apparatus commonly used in the art may be, for example, a mobile device such as a mobile phone, a wearable device such as a watch, a VR device, or the like. Those skilled in the art may make corresponding selections according to the specific application of the display apparatus, which will not be described in detail herein.

It should be noted that, in addition to the display panel, the display apparatus further includes other necessary components and compositions, such as a housing, a circuit board, a power line, and the like. Those skilled in the art may supplement the display apparatus according to specific use requirements, which will not be described in detail herein.

Other embodiments of the present disclosure will be readily apparent to those skilled in the art upon consideration of the specification and practice of the inventions disclosed herein. The present disclosure is intended to cover any variations, uses, or adaptations of the present disclosure that follow the general principles of the present disclosure and include common knowledge or conventional technical means in the art that are not disclosed in the present disclosure. The specification and examples are merely exemplary, and the true scope and spirit of the present disclosure are indicated by the appended claims.

What is claimed is:

1. An array substrate, comprising:
a base substrate;
a first conductive layer disposed on a side of the base substrate, the first conductive layer comprising a source electrode and a drain electrode;
a first electrode disposed on a side of the first conductive layer away from the base substrate, an orthographic projection of the first electrode on the base substrate being overlapped with an orthographic projection of the drain electrode on the base substrate;
an organic planarization layer disposed on a side of the first electrode away from the base substrate, the organic planarization layer being provided with first via holes, and the first via holes being connected to the source electrode and the drain electrode, respectively;
an organic active layer disposed on a side of the organic planarization layer away from the base substrate, the organic active layer being connected to the source electrode through the first via hole and connected to the drain electrode through the first via hole.

2. The array substrate according to claim 1, wherein an angle between a hole wall of the first via hole and a face of the first conductive layer away from the base substrate is less than or equal to 70°.

3. The array substrate according to claim 1, wherein an area of the organic planarization layer corresponding to a display area of a sub-pixel is provided with an opening portion.

4. The array substrate according to claim 3, wherein an orthographic projection of the display area on the base substrate is within an orthographic projection of the opening portion on the base substrate.

5. The array substrate according to claim 1, further comprising:
a gate insulating layer set disposed on a side of the organic active layer away from the base substrate, an orthographic projection of the gate insulating layer set on the base substrate being overlapped with an orthographic projection of the organic active layer on the base substrate;
a first gate electrode layer disposed on a side of the gate insulating layer set away from the base substrate, the first gate electrode layer comprising a first gate electrode.

6. The array substrate according to claim 5, wherein the gate insulating layer set comprises:
a first gate insulating layer disposed on a side of the organic active layer away from the base substrate;
a second gate insulating layer disposed on a side of the first gate insulating layer away from the base substrate, performance of the second gate insulating layer blocking an etching solution of the first gate electrode layer being stronger than performance of the first gate insulating layer blocking an etching solution of the first gate electrode layer.

7. The array substrate according to claim 5, wherein an orthographic projection of the first gate electrode on the base substrate is within an orthographic projection of the organic active layer on the base substrate.

8. The array substrate according to claim 7, wherein the organic active layer comprises a conductor portion, and an orthographic projection of the conductor portion on the base substrate is not overlapped with the orthographic projection of the first gate electrode on the base substrate.

9. The array substrate according to claim 8, wherein in the first direction, a distance between two first via holes of a thin film transistor is larger than a width of the first gate electrode.

10. The array substrate according to claim 5, further comprising:
a passivation layer disposed on a side of the first gate electrode layer away from the base substrate;
a second electrode layer disposed on a side of the passivation layer away from the base substrate.

11. The array substrate according to claim 10, further comprising:
a second gate electrode layer disposed between the passivation layer and the second electrode layer, wherein the second gate electrode layer comprises a second gate electrode and a second gate line, the second gate electrode is connected to the first gate electrode, the second gate line extends along a first direction, the second gate line is connected to a plurality of second gate electrodes disposed along the first direction, and the first direction is parallel to a face of the base substrate close to the first conductive layer.

12. The array substrate according to claim 5, wherein the first gate electrode layer further comprises a first gate line, the first gate line extends along a first direction, the first gate line is connected to a plurality of first gate electrodes disposed along the first direction, and the first direction is parallel to a face of the base substrate close to the first conductive layer.

13. The array substrate according to claim 10, further comprising:
a protective layer covering at least a sidewall of the organic active layer.

14. The array substrate according to claim 13, wherein the protective layer is disposed between the gate insulating layer set and the first gate electrode, and between the organic planarization layer and the passivation layer, and covers sidewalls of the organic active layer and the gate insulating layer set.

15. The array substrate according to claim 13, wherein the protective layer is disposed between the first gate electrode layer and the organic planarization layer and the passivation layer, and covers sidewalls of the organic active layer, the gate insulating layer set, and the first gate electrode, and compatibility between the protective layer and the organic active layer is stronger than compatibility between the passivation layer and the organic active layer.

16. The array substrate according to claim 1, wherein a work function of the first conductive layer is greater than 4.5 eV.

17. The array substrate according to claim 1, wherein the array substrate is a flexible array substrate.

18. A display panel, comprising:
an array substrate according to claim 1;
a color film substrate disposed opposite to the array substrate;
a liquid crystal layer disposed between the array substrate and the color film substrate.

19. The display panel according to claim 18, wherein the array substrate is a flexible array substrate, and the color film substrate is a flexible color film substrate.

20. A display apparatus, comprising: a display panel according to claim 18, the display apparatus being a rollable display apparatus, a foldable display apparatus or a curved display apparatus.
